(19) United States
(12) Patent Application Publication
(10) Pub. No.: US 2010/0277627 A1
(43) Pub. Date: Nov. 4, 2010

(54) Image Sensor

(76) Inventors: Jacques Duparré, Jena (DE); Frank Wippermann, Meiningen (DE); Andreas Bräuer, Schloben (DE)

Correspondence Address: GIBSON & DERNIER LLP, 900 ROUTE 9 NORTH, SUITE 504, WOODBRIDGE, NJ, 07095, US

(21) Appl. No.: 12/677,169

(22) PCT Filed: Sep. 24, 2008
(86) PCT No.: PCT/EP08/08090

§ 371 Date: May 5, 2010

(30) Foreign Application Priority Data
Sep. 24, 2007 (DE) 10 2007 045 525.0

(51) Int. Cl. H04N 5/335; H01L 27/146; H01L 27/148; H01L 31/18

(52) U.S. Cl. 348/262; 250/208.1; 438/65; 348/E05.091; 257/E31.11

(57) ABSTRACT

Image sensor having a large number of image sensor units in an essentially array-like arrangement, the light-sensitive surfaces of the image sensor units being node points at a spacing relative to each other and these, together with the horizontal and vertical connection lines which connect the node points, spanning a two-dimensional network, and the array-like arrangement having a central region and an edge region, the central region and the edge region being connected to each other along at least connection line, characterised in that the spacing respectively of two adjacent node points of the array-like arrangement is different along the at least one connection line in the central region and in the edge region. Furthermore, a camera system with an image sensor according to the invention and an additionally disposed lens system is disclosed.

The invention relates to an image sensor having a large number of image sensor units in an essentially array-like arrangement.

Image sensors are used wherever an image of an object for viewing or further processing by means of a data processing unit is intended to be made available. Essentially, an imaging lens system, an image sensor with associated electronics and a data processing unit are hereby used.

Lens systems for image production naturally have different image errors, so-called aberrations. There can be mentioned here for example spherical aberration, coma, astigmatism, field curvature, distortion errors, defocusing and longitudinal or transverse colour errors. Usually, it is attempted here by means of special lens design, such as for example aspherical lenses or a combination of different lens shapes and also different materials, to compensate for the image errors. However, with the help of the lens design, the aberrations can be corrected only to a certain degree, different aberrations acting in opposite directions during the correction, i.e. the correction of one aberration leads to deterioration in another aberration. For this reason, it must be decided already during the lens design which qualities the camera system is intended to fulfil as a whole and/or on which image properties particular emphasis is placed. This leads in general to the definition of a quality function which is then used as a measure during lens optimisation. The production of lenses with complex aberration correction is in addition often very costly since the complicated surface geometry is difficult to produce and must take place in tedious operating steps and/or exotic materials must also be used with many lenses.

A further approach for correction of the aberrations resides in subsequently correcting or even removing, by subsequent digital processing of the images (“remapping”), the aberrations which result merely in a distortion of the image but not in lack of focus. The disadvantage in this solution is that in order to calculate the transformations from the uncorrected image to form the corrected image, memory and in particular computing time is required. Furthermore, it must be interpolated between the actual pixels of the image sensor, i.e. either finer scanning is required or resolution is forfeited.

A further possibility of partially correcting aberrations resides in configuring the image sensor rotationally symmetrically. The disadvantage hereby is however that, with conventional displays or printers, the thus recorded images cannot be directly reproduced since the image pixels there are located in a virtually rectangular arrangement. Hence, an electronic redistribution of the image information is also required here, which leads to the disadvantages in the previously mentioned paragraph.

It is the object of the invention to produce an image sensor and/or a camera system which makes it possible to undertake some aberration corrections with the help of the image sensor so that mutually restricting aberration corrections in the lens system can be avoided. Furthermore, with the image sensor, only low requirements on memory and computing time of an electronic system or subsequently connected data processing unit should be required.

The object is achieved with an image sensor having the features of claim 1, a camera system having the features of claim 25 and a method having the features of claim 30. The further dependent claims reveal advantageous developments.

The image sensor having multiple image sensor units has an array-like construction. As a result, the current standards of displays and printers are taken into account. The array thereby has a coordinate system comprising node points and connection lines, the light-sensitive surfaces of the image sensor units being disposed respectively at the node points. The coordinate system is not a component of the array but serves for orientation similarly to a crystal lattice. The connection lines are hereby vertical or horizontal in the sense that they extend from top to bottom or left to right. It is hence intended in no way that the vertical or horizontal connection lines are necessarily straight or extend parallel to each other. For this reason, it is sensible to describe them as a network with connection lines and node points instead of a grid in order to preclude any linguistic misinterpretation.

The array-like arrangement has a central region and an edge region, the central region and the edge region being connected to each other along at least one connection line. It is thereby established that the central region and the edge region are not disjoint sets but merge into each other fluidly. As a result of the fact that the spacing respectively of two adjacent node points, i.e. the locations at which the light-sensitive surfaces of the image sensor units are disposed along the at least one connection line which connects the central and the edge region to each other is different in the central region and in the edge region, different aberrations can be corrected by the geometry of the image sensor and/or the image sensor units disposed thereon so that, in particular in the correction, oppositely acting aberrations need not be corrected exclusively by a possible objective and/or lens system. By producing additional suitable degrees of freedom in the image sensor, more degrees of freedom are achieved in the optimisation of the lens system. This results consequently in better possibilities for resolving how to apportion the corrections of the various aberrations to a lens system, an image sensor and a data processing unit. The advantage is thus produced for example that, with a subsequent image processing, less time and memory requires to be allocated since the image sensor is disposed, on the one hand, in an array-like manner, however an electronic redistribution of the image information from the individual image sensor units is not required since this is effected already firmly preformed at the image sensor level. The region of the image sensor which is penetrated by the optical axis of an associated lens is termed central region.

Image sensors according to the state of the art are constructed as an equidistant array of image sensor units. Optical errors occur usually at an increasing distance from the optical axis of a lens arrangement and become greater towards the edges of the image sensor. A fixed spacing between all the individual sensor units relative to each other merely ensures that the imaging errors are visible also on the recorded image. By means of a different spacing of two light-sensitive surfaces in the central and in the edge region, correction terms at the edge region can be taken into account so that the image in fact continues to have the imaging error but the light-sensitive surfaces are disposed such that the recordings made in an equidistant image point display with the image sensor units are free of imaging errors. Hence, the result is better imaging of beam paths which either do not run through the centre of the lens or impinge at large angles and are imaged on the image sensor.

If in addition the spacing of a second connection line, which is parallel at least at one location to the first connection line (along which the spacing of two light-sensitive surfaces changes from the central to the edge region), relative to the first connection line changes likewise from the central to the edge region, a spacing variation is found not only along one dimension but also in the second dimension of the image sensor.

As a result of the fact that the equidistant arrangement of the light-sensitive surfaces of the image sensor units is resolved in the image sensor according to the invention and hence forms a non-equidistant network, a large number of possibilities is offered for improving the quality of images as a result of the above-mentioned advantages and can be used to avoid aberrations. (Already with the available structuring techniques, economic feasibility should no longer play a great role after a short introductory phase.)

Further advantages are described in the subordinate claims.

As a result of the fact that the spacing of two adjacent node points changes constantly along the at least one connection line from the central region to the edge region, the increasing importance of the correction terms is taken into account, which are usually described by square, cubic or even higher powers of the imaging-describing angles. Since a large number of image sensor units can be situated along the one connection line between the central region and the edge region, it is advantageous if the spacing of two light-sensitive surfaces relative to the spacing of two light-sensitive surfaces in the edge region changes constantly since a continuous correction of aberrations towards the edge region can thus be undertaken.

It is particularly advantageous if the spacing respectively of two adjacent node points of the array-like arrangement of the image sensor units changes from the central region to the edge region in order to compensate for the geometric distortion, the correction of a lens system being able to be undertaken independently or dependently. The distortion is subdivided into a positive distortion, i.e. a pin-cushion-shaped distortion and a negative distortion, i.e. a barrel-shaped distortion. Since the geometric distortion effects only a change in the enlargement with the angle of incidence, i.e. an image point offset relative to the ideal case but no enlargement of the focus, i.e. the point image fading function and hence a reduction in resolution, this is particularly suitable for being corrected at the image sensor level by displacement of the correspondingly associated detector pixels. The distortion is the deviation of the real main beam position in the image sensor plane from the position of the ideal and/or paraxially approximated main beam. This results in a variable enlargement over the image field and hence to distortion of the total image. Whilst the ideal and/or paraxially approximated image field coordinate yₚ is proportional directly to the tangent of the angle of incidence Θ, the real image field coordinate y deviates therefrom. The deviation from the tangent is the distortion and typically goes approx. with Θ̂3 or a complicated curve. As a measure of the distortion, (y−yₚ)/yₚ is hereby used: if the real image field coordinate is greater than the ideal image field coordinate, the distortion is pin-cushion-shaped, otherwise barrel-shaped. In the case of a pin-cushion-shaped distortion, the spacing of the light-sensitive surfaces, as a function of the radial spacing of the observed detector pixel from the centre of the image sensor, i.e. diagonally stronger than horizontally or vertically, becomes greater from the central region towards the edge region, with a barrel-shaped distortion, becomes smaller.

In the production of the image sensor with incorporated distortion correction, the position of the real main beam is correspondingly compared with the ideal main beam, and the light-sensitive surface is displaced by the spacing of the two beams outwards (in the case of a pin-cushion-shaped distortion) or inwards (in the case of a barrel-shaped distortion) to the position of the real main beam.

A development of an image sensor according to the invention is to configure the array-like arrangement in the form of a rectilinear grid. Hence the change in spacing from the centre to the edge region is undertaken only in one dimension of the array. This means that the spacing of the light-sensitive surfaces relative to each other in the first dimension of the image sensor remains constant, in the second dimension changes from the central to the edge region, preferably along a large number of connection lines in the second dimension. Thus an image sensor which is configured to be very narrow but oblong can be configured in the longitudinal dimension to be normal in the first dimension, since in the latter the distortion remains small.

A further advantageous development is if the correction is undertaken in both dimensions of the array. In this case, the connection lines can be displayed as a parameterised curve but no longer as a straight line. Should the spacings change from the central to the edge region along a large number of connection lines (and in fact also the spacing of the connection lines as a function of the radial coordinate), then the array-like arrangement can be displayed as a curvilinear grid, i.e. comprising a large number of parameterised curves. In this way, an aberration can be compensated for in two dimensions. Preferably, the spacing of two adjacent light-sensitive surfaces changes from the central to the edge region along a large number of connection lines in both array dimensions. Hence the curvilinear grid forms a two-dimensional extension of the rectilinear grid.

It is an advantageous arrangement if the edge region of the image sensor surrounds the central region of the image sensor completely. The advantage hereby is that, starting from the central region, further image sensor units are disposed in each direction and thus an image sensor region surrounds the optical axis. As a result, the compensation for the aberration, advantageously the geometric distortion, from the central region of the image sensor in all directions of the image sensor plane, can be effected.

A further advantageous development is if the large number of image sensor units is disposed on one substrate. This has advantages in particular in production since an application of current structuring techniques is possible. Furthermore, it is advantageous when the image sensor units are optoelectronic and/or digital units.

It is particularly advantageous if the light-sensitive surface of an image sensor unit is disposed respectively in the centre of this image sensor unit. In this way, not only do the spacings of the light-sensitive centres of the image sensor units shift relative to each other but also the spacings of the image sensor units relative to each other. As an alternative hereto, exclusively the light-sensitive surfaces can change their spacing, which leads to the fact that these cannot be found exclusively in the centre of an image sensor unit. Both alternatives can also be produced within one image sensor. Furthermore, it is advantageous if the light-sensitive surface is a photodiode or a detector pixel, in particular a CMOS, or are a CCD or organic photodiodes.

A further advantageous arrangement is if at least one image sensor unit has a microlens and/or if the large number of image sensor units is covered by a microlens grid. Furthermore, further aberrations can be compensated for with the help of the microlenses, which aberrations are otherwise corrected within a preceding imaging lens system if the latter have variable geometric properties over the image field of the lens system, such as tangential and sagittal radii of curvature which can be adjusted separately from each other and variably.

A further advantageous development of the image sensor provides that the microlens and the microlens grid are configured to increase the filling factor. As a result, a light bundle impinging on an image sensor unit can be concentrated better onto the light-sensitive surface of an image sensor unit, which leads to an improvement in the signal-to-noise ratio.

Advantageously, by adapting the radii of curvature and/or the ratios of the radii of curvature of the microlenses of a plurality of image sensor units and/or of ratios of radii of curvature of the microlenses in the two main axes of the array, an astigmatism and/or field curvature can be corrected with the help of the microlenses and/or the astigmatism and the field curvature of the microlenses can be corrected. This makes possible also the displacement of corrections from one imaging lens system towards the image sensor, which again opens up degrees of freedom in the design of the imaging lens system. In this way, an improved focusing onto the light-sensitive surfaces (offset to the position corresponding to the main beam angle) can take place due to the microlenses so that, with the help of the adapted microlens shape, a better image is possible.

In order to obtain as small a diffraction disc as possible in the focus in the case of an oblique incidence of the light bundle onto a microlens, advantageously elliptically chirped microlenses, i.e. over the array microlenses with variably adjustable parameters, are used, which depend, in their orientation, size in both main axes and their radii of curvature along the main axis of a microlens, upon the angle of incidence of the main beam of the preceding imaging lens system. In contrast to circular microlenses, an astigmatism produced during the focusing by the microlens array at a large angle of incidence and a field curvature are hence reduced.

In order to correct a chromatic aberration, an image sensor unit can advantageously have a colour filter and/or the large number of image sensor units can be connected to a colour filter grid. For a colour image recording generally 3 basic colours are used, i.e. for example red, green and blue, or magenta, cyan blue and yellow, the colour pixels being disposed for example in a Bayer pattern. Colour filters—like the microlenses—are offset in order to adapt to the main beam of the lens system at the respective position of the array.

Furthermore, the colour filters, analogously to the microlenses, can be relatively offset relative to the light-sensitive surfaces in order to compensate, on the one hand, for the lateral offset of the focus on the photodiode resulting from the main beam angle, or to compensate for a distortion but also to enable better assignment of the individual colour spectra to the light-sensitive surface in the case of chromatic transverse aberrations. The offset of the colour filters and assigned pixels thereby corresponds to the offset of the different imaged colours due to chromatic transverse aberrations.

The camera system according to the invention is distinguished in that the image sensor is in communication with a preceding imaging lens system in a planned and permanent manner. Since, because of the different corrections, degrees of freedom are produced in the lens design, in particular good coordination between the lens system and the image sensor makes a quality jump possible. The image sensor is disposed in the image plane of the lens system.

In an advantageous embodiment of the image sensor and/or of the camera system, the size of the image sensor units and/or the light-sensitive surfaces thereof is variable and hence are different for at least some of the image sensor units in one image sensor. It is consequently possible to make use of the space, obtained by distortion, towards the edge of the image sensor in addition, as a result of which greater light-sensitivity is achieved with a larger surface area of the photodiodes. As a result, the edge decrease in brightness can be compensated for and consequently the relative illumination strength can be improved.

In a further advantageous embodiment, the transverse colour error can be corrected on the image sensor side in that the colour filters are disposed on the detector pixels, adapted to the transverse colour error of the lens system, so that the transverse colour error of the lens system can be compensated for. In order to correct the transverse colour error it is possible furthermore to calculate the colour pixel signals. The colour filters, starting from the normal Bayer pattern or from conventional demosaicing, can hereby be disposed deviating from the Bayer pattern and/or demosaicing and a known transverse colour error can be calculated therefrom by means of image processing algorithms. Different detector pixels, possibly further removed from each other, of different colours can be calculated thereby to form one colour image point. It is also possible here to allow an increased transverse colour error for the lens system or artificially to increase also the transverse colour error in order consequently to open up degrees of freedom for the correction of other aberrations.

In a further embodiment, the image sensor can be configured on a curved surface so that curvature of the image field can be corrected. It is hereby particularly preferred if the image sensor units and/or the light-sensitive surfaces have or are organic photodiodes since these can be produced particularly favourably on a curved base.

The distortion of the lens system can be increased in the lens design or left open in order to be able to correct other aberrations better. By relaxing the requirement with respect to the distortion even during the planning of the optical design and the correction of this distortion via the design of the image sensor, properties, such as e.g. the resolution, can be significantly improved, even if they cannot be corrected easily by displacement of the pixels. This procedure is particularly advantageous with wafer level optics, where it makes sense, because of the large number of parts, to coordinate an image sensor to only one single lens design since lens and image sensor are designed simultaneously in cooperating companies or in the same company as components for only this one camera system. Such cameras can be used for example as mobile telephone cameras. In this case, the distortion of an already existing lens need not be measured and a lens design need not be determined from the latter via simulation, instead lens system and image sensor can be optimally designed as a total system, the problem of the distortion correction being moved from the lens system to the image sensor (this means that a distortion of the lens system can be permitted in an increased manner in order to produce other degrees of freedom for the lens system, such as for example for improvement in resolution or resolution homogeneity). Cheaper production of the camera system can also be made possible.

In the camera system, elliptical, chirped microlenses can be used on the image sensor, with which focusing adapted to the angle of incidence into the pixels is possible. The microlenses can hereby be designed with parameters which are altered radially monotonously over the array, such as for example tangential and sagittal radius of curvature. The image sensors, simultaneously corresponding to the main beam angle and corresponding to the distortion of the imaging lens system, can be disposed offset relative to a regular array. The geometry of the individual microlenses of a microlens system increasing the filling factor (radii of curvature, ratios of radii of curvature in the two main axes over the array of varying non-rotationally symmetrical microlenses) can therefore be adapted to the main beam angle of the bundle to be focused by the respective lens.

A correction of astigmatism and field curvature of the microlenses can be achieved by adaptation (lengthening) of the radii of curvature in the two main axes of elliptical lenses, with which optimal focusing onto the photodiodes is possible, which are offset to the position corresponding to the main beam angle and distortion. The microlens shape can be adapted therefore to the main beam angle, as also the offset of pixels and microlenses corresponding to the distortion. Also a rotation of the elliptical lenses corresponding to the image field coordinate is possible such that the long one of the two main axes extends in the direction of the main beam. Both the radii of curvature and the ratios of the radii of curvature and the orientation of the lens at a constant photoresist thickness in the reflow process can be adapted via the axis size and the axis ratio and also the orientation of the lens base. As a result, in total a larger image-side main beam angle can be accepted, which opens up further degrees of freedom for the lens design.

There are applied particularly advantageously a camera system or an image sensor according to the invention in a camera and/or in a portable telecommunications device and/or in a scanner and/or in an image detection device and/or in a monitoring sensor and/or in an earth and/or star sensor and/or in a satellite sensor and/or in a space travel device and/or a sensor arrangement. In particular the use in the monitoring of industrial plants or individual parts hereof is possible since the sensor and/or the camera system can produce exact images without high computing complexity. Also use in microrobots is possible because of the small size of the sensor. Furthermore, the sensor can be used in a (micro) endoscope. Also use in the field of the human eye as a visual aid can be sensible by means of intelligent connection to nerve cells. Because of the increased imaging qualities, the image sensor according to the invention and/or the camera system according to the invention is suitable in all fields in which access would be desired to images of the highest quality via data processing units and the images are intended to be available in real time.

Advantageously, the image sensor and/or the camera system is produced in such a manner that, in a first step, the distortion of a planned or already produced lens system is determined and thereupon an image sensor is produced in which the geometrical distortion of the lens system is compensated for by the arrangement of the light-sensitive surfaces and/or the image sensor units, at least partially. As a result of the fact that now the distortion of the lens system need no longer be kept low, better resolution for example can be achieved without increasing the complexity of the lens system. Thus “normal” lenses with geometric distortion can also be corrected subsequently with an image sensor. Further aberrations can likewise be corrected.

Further advantages are described in the further subordinate and coordinated claims.

The invention is intended to be described subsequently in more detail with reference to a large number of Figures. There are shown:

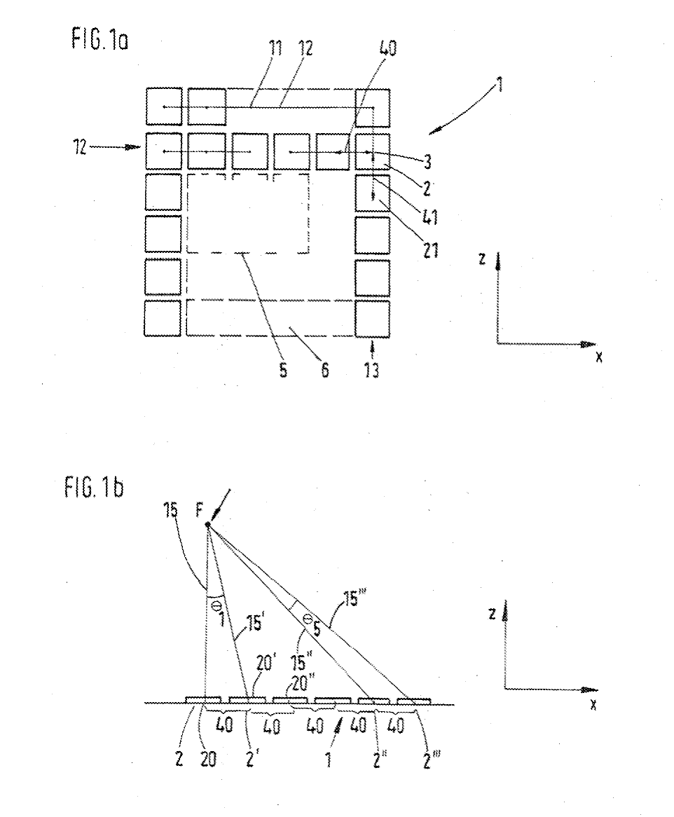

FIGS. 1a and 1b image sensor and beam path according to the state of the art;

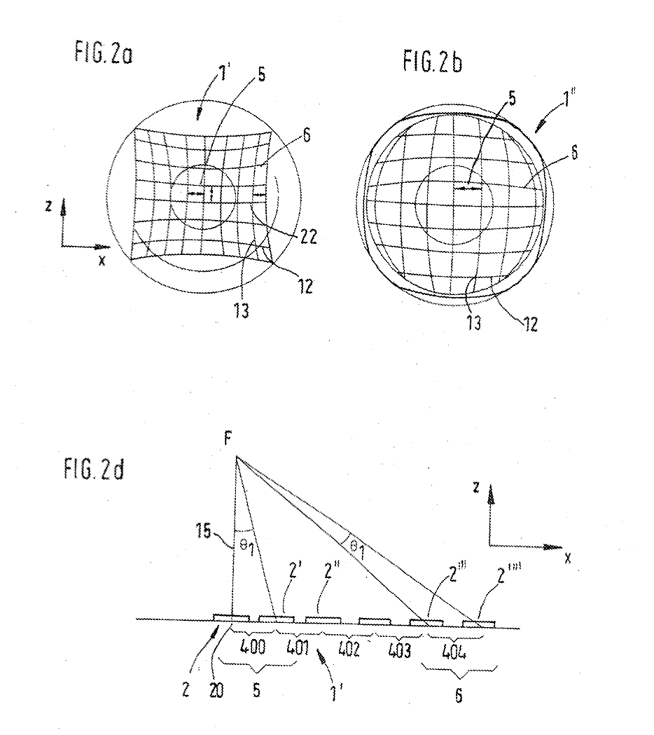

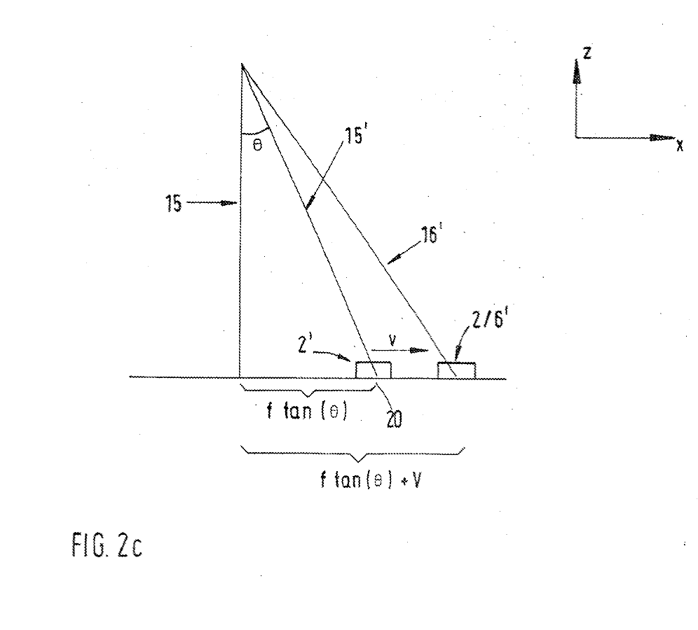

FIGS. 2a and 2b schematic representation of an image sensor according to the invention with array for correction of an aberration, in particular a geometric distortion;

FIG. 2c transverse view with illustration of the offset, according to the invention, of a pixel;

FIG. 2d transverse view on a sensor for correction of a pin-cushion-shaped geometric distortion;

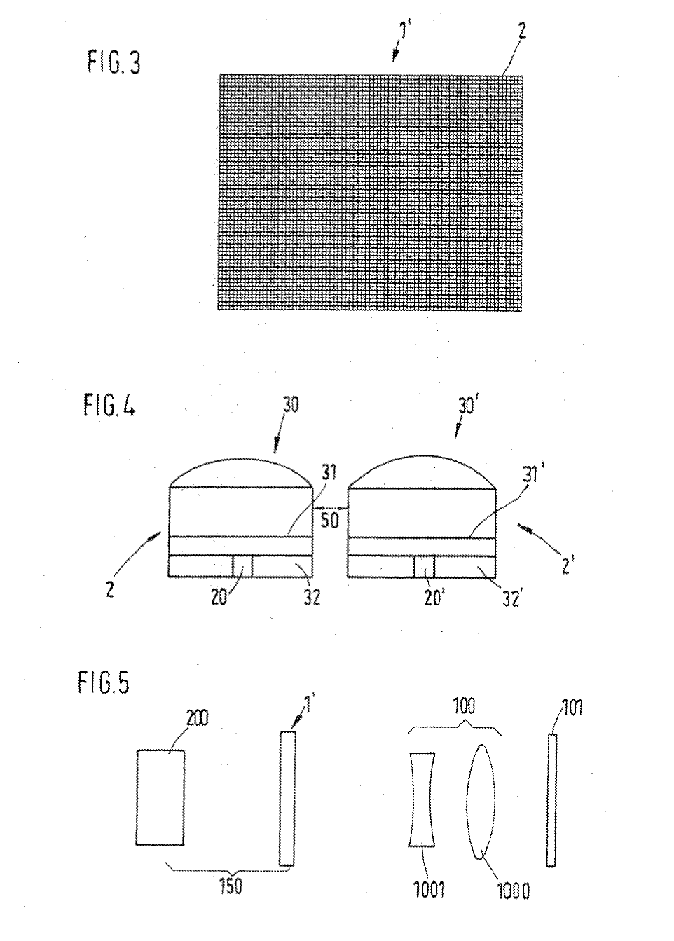

FIG. 3 image sensor with pin-cushion-shaped distortion;

FIG. 4 arrangement of two image sensor units with associated microlenses, pinhole array and colour filter grid;

FIG. 5 camera system according to the invention;

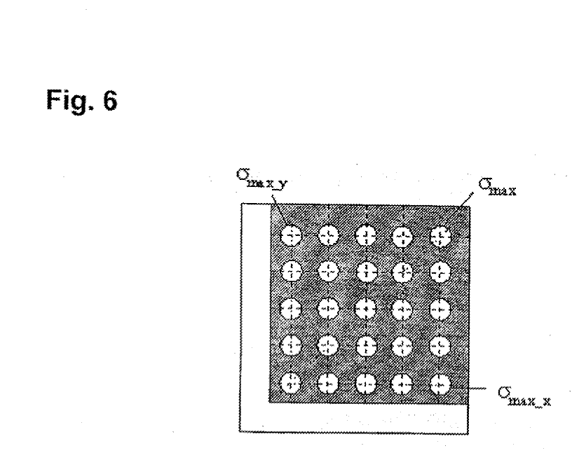

FIG. 6 the right upper quadrant of a regular array of round microlenses;

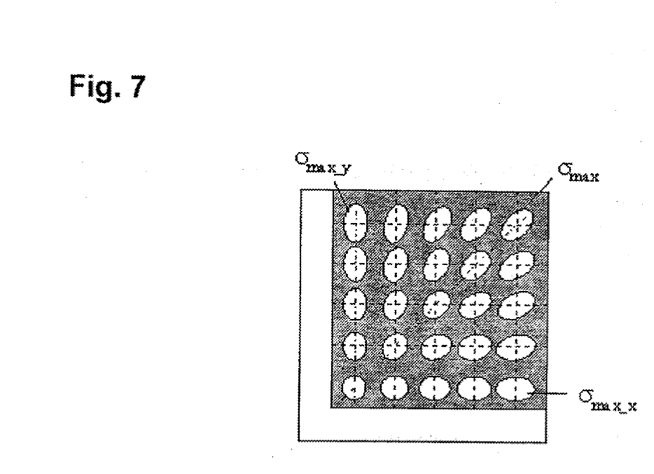

FIG. 7 the right upper quadrant of a chirped array of anamorphic and/or elliptical microlenses;

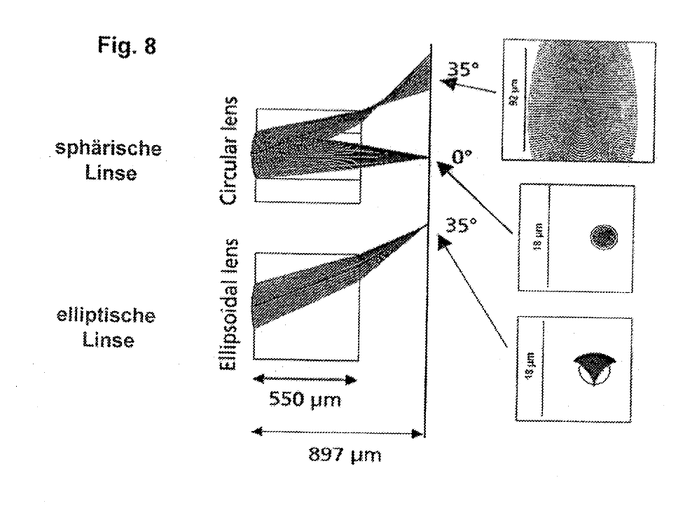

FIG. 8 beam path and spot distribution for a spherical lens with vertical and oblique light incidence (top) and for an elliptical lens with oblique incidence (bottom). With an elliptical lens adapted to the direction of incidence, a diffraction-limited focus can be achieved in the paraxial image plane;

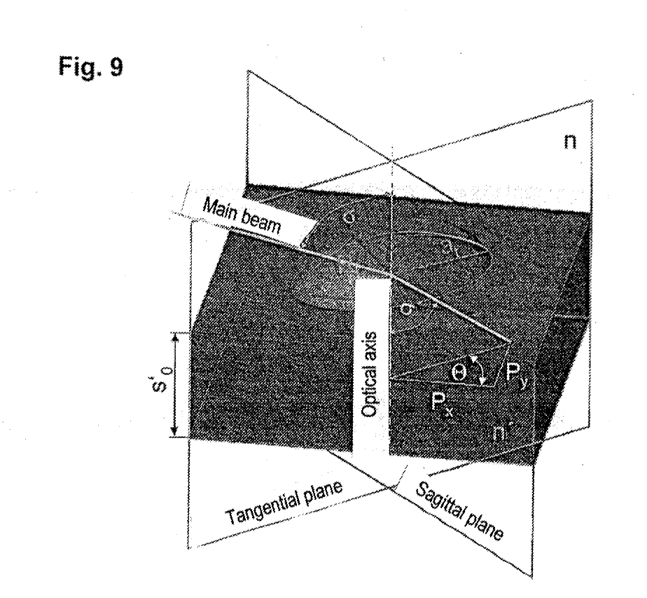

FIG. 9 a diagram which shows the geometry of an elliptical lens;

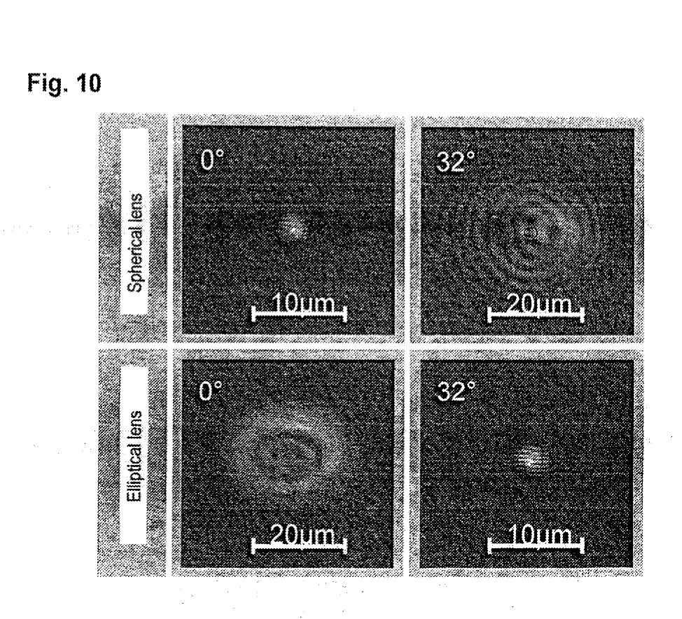

FIG. 10 the measure intensity distribution in the paraxial image plane for vertical and oblique light incidence for a spherical and an elliptical lens. Circles mark the diameter of the Airy disc.

In FIGS. 1a and 1b, the construction of an image sensor according to the state of the art is represented. In FIG. 1a, a view on an image sensor 1 which has a large number of sensor units is shown, a few image sensor units 2, 2′, 2″ being described by way of example. The image sensor units are thereby disposed in the form of an array, the array having node points (by way of example 11, 11′, 11″) and being orientated in X direction along the connection line 12 and in Y direction along the connection line 13. Thus the image sensor units 2, 2′, 2″ are disposed such that the light-sensitive surfaces are disposed in the centre of an image sensor unit and the centre of the image sensor unit is situated on one of the node points 11. The network therefore represents a coordinate system within the sensor. In the state of the art, the spacings between two adjacent light-sensitive surfaces are identical, both along the connection lines in X direction and along the connection lines in Y direction. This means that, for example along the connection line 12, the spacing 40 between the light-sensitive surfaces of the image sensor units 2 and 2′ and the further sensor units situated adjacently on the left is identical. The spacings 41 between the light-sensitive surfaces of the image sensor units along the connection line 13 are the same. Also the spacings 40 and 41 are hereby the same. This means in particular that the horizontal connection lines 12 are situated parallel to each other and the vertical connection lines 13 are situated parallel to each other.

In the centre, the image sensor 1 illustrated here has a central region 5 and, at the edge, an edge region 6 which surrounds the central region.

The light-sensitive surface of an image sensor unit is formed by a photodiode or a detector pixel.

In FIG. 1b a view of the image sensor 1 in the XZ plane is shown. Starting from a point F, light beams 15, 15′, 15″ and 15′″ impinge on different image sensor units 2 and/or 2, 2′, 2″, 2″′ which are all disposed along the connection line 12. The spacings 40 respectively of two adjacent pixels 20 which are situated in the centre of an image sensor unit 2 are the same along the connection line. The distance between the light-sensitive surface 20 of the image sensor unit 2 and the point F corresponds to the image distance of a lens system which is assigned to the image sensor. Although the spacing between two adjacent pixels 20 is the same, different angle segments are covered between two adjacent pixels 20. This is of no significance however for the imaging since the image—apart from a possible enlargement or reduction—correctly reproduces the object to be imaged. The illustrated main beams 15, 15′, 15″ and 15″′ are thereby ideal main beams, i.e. the imaging is distortion-free.

In FIGS. 2a, 2b, the connection lines 12, 13 and connection points of two image sensors according to the invention 1′, 1″ are shown schematically. Both are different in the spacing of their node points, at which the light-sensitive surfaces of the image sensor units are situated, in the central region 5 and in the edge region 6. The spacings of two adjacent light-sensitive surfaces therefore change from the centre to the edge region, the spacing between two pixels 20 is supplemented by a correction term which corresponds precisely to the spacing between ideal and real main beam, i.e. the pixel being applied at the location of the real main beam. If the recorded image data are now displayed with an equidistant array, as is the case normally for monitors or printers, then the image has no distortion.

In the case of a positive distortion, then a pin-cushion-shape arrangement of the array of the image sensor 1′ is produced since the spacings between two light-sensitive surfaces are smaller in the centre than the spacings of two light-sensitive surfaces in the edge region. This is illustrated in FIG. 2a. In FIG. 2b, an image sensor 1″ with a barrel-shaped distortion is shown, in which the spacings of two adjacent light-sensitive surfaces are greater in the central region than the spacings of two light-sensitive surfaces in the edge region along the same connection line.

It is also conceivable that the spacings of two light-sensitive surfaces do not change continuously along a connection line, as indicated in FIGS. 2a and 2b, but that the spacing is equidistant in the central region and is equidistant in the edge region, in that the spacings in the central region and in the edge region are however different. As a result, in particular effects which occur exclusively at the edge of an image sensor could be compensated for without requiring entirely to take into account the complex constant development of the spacing of two light-sensitive surfaces. The shape of the image sensor units shown here is rectangular or square but can also turn out to be round or polygonal.

It is illustrated schematically in FIG. 2c how a single pixel is offset in order to enable a correction of a geometric distortion already on the image sensor plane. An ideal main beam 15′ and the associated real main beam 16′ is illustrated. The pixel 20 of the image sensor unit 2′ is situated in the focus of the ideal main beam. The pixel 20 is now displaced by the spacing V (in reality, the pixel is of course not displaced but disposed similarly at the relevant position), V being the correction term of the geometric distortion and being able to be determined from theoretical calculations or measurements of a lens system. The image sensor unit 2′ is displaced to the position 216′ although an offset of the pixel 20 itself likewise suffices. The correction term is thereby dependent upon the type of geometric distortion and the spacing from the optical axis 15 of the associated optical lens system.

In FIG. 2d, a view of a section of the image sensor 1′ of FIG. 2a in the XZ plane is shown. A main beam 15, starting from point F, is thereby in the centre of the image sensor 1′ and impinges vertically on the latter. In the embodiment represented here, the light-sensitive surfaces 20 sit in the centre of the image sensor units 2. It can be seen clearly that the spacings 400, 401, 402, 403 and 404 increase with increasing X direction. The image sensor units 2, 2′, 2″ can thereby be assigned to the central region 5 and the image sensor units 2″′ and 2″′ to the edge region 6. As described in FIG. 2c, each pixel is thereby disposed, deviating from the position of the associated ideal main beam, at the position of the associated real main beam. The associated ideal main beam is thereby prescribed by an equidistant array arrangement. For arrangement of the individual pixels, the real main beams are however used so that a non-equidistant arrangement of the pixels is produced.

As a result of the hardware arrangement of the light-sensitive surfaces of the image sensor, the distortion and/or the course of the distortion of the lens to be used is already incorporated in the image sensor itself. As a result, the object points imaged offset from the lens relative to the paraxial case are imaged also on correspondingly offset receiver pixels. The assignment between object points and image points hence corresponds exactly and, as a result of simple data read-out and arrangement of the image pixel values, a distortion-free or low-distortion digital image is produced.

In FIG. 3, an image sensor 1′ is shown, each individual sensor unit 2 having a unit comprising filling factor-increasing microlens, colour filter (e.g. in Bayer arrangement, i.e. adjacent detector pixels have different colour filters (red, green, blue)) and detector pixels. The pin-cushion-shaped arrangement of the image sensor units for correction of the distortion of the lens used for the imaging corrects an approx. 10% distortion. The percentage date hereby relate to the deviation of an ideal and/or paraxial image point from the real image field point, standardised by the coordinate of the ideal and/or paraxial image point.

In FIG. 4, two adjacently situated image sensor units 2 and 2′ of an image sensor according to the invention are represented. The image sensor units thereby have respectively a microlens 30 or 30′, respectively, these being able, in combination with all other image sensor units as shown in FIG. 3, to be configured as a grid and hence likewise image the different spacings of the image sensor units relative to each other so that a distorted microlens structure is produced. The same applies to the colour filters 31 or 31′ respectively, which can likewise be configured as a grid or a distorting grid.

With the help of the microlenses 30, 30′ and/or microlens arrays, an increase in the filling factor can be achieved so that the filling factor of the light-sensitive surface within an image sensor unit can be of the order of magnitude of around 50% but nevertheless nearly all the light which falls on an image sensor unit can be converted by the concentration on the photodiode into an electrical signal. Furthermore, pinholes 32 or 32′ are situated respectively on the image sensor units 2 or 2′, respectively, in the recess of which pinholes the light-sensitive detector unit 20 or 20′, respectively, is disposed. The pinhole array with the pinholes 32, 32′ can thereby be configured such that the spacings of adjacently situated light-sensitive surfaces 20 or 20′, respectively, change from the centre to the edge region but the spacings 50 between two adjacent image sensor units remain the same.

The geometry of the individual microlenses 30, 30′ of the microlens array increasing the filling factor is adapted to the main beam angle of the bundle to be focused by a respective lens system; this takes place by a variation in the radii of curvature of the microlenses along a connection line, and/or the ratio of radii of curvature of a single microlens in the two main axes X and Y relative to each other, the two radii of curvature within one microlens being able to vary over the array along a connection line and the microlenses being able to be of a non-rotationally symmetrical nature. By means of the microlenses, for example an astigmatism or a field curvature can be corrected by corresponding adaptation of the radii of curvature in the two main axes with formation of elliptical microlenses. Hence optimal focusing on the photodiodes 20 which are offset from the centre of the image sensor unit corresponding to the main beam angle can therewith be achieved. The offset of the photodiodes is not thereby crucial but rather the adaptation of the microlens shape to the main beam angle. Also the fitting of elliptically chirped microlenses, in which the radii of curvature and the ratio of the radii of curvature are adjusted exclusively via the axis size and the axis ratio and the orientation of the microlens base, is sensible. In this way, possibly a larger image-side main beam angle can be accepted. This opens up further degrees of freedom for the lens design since further aberrations on the image sensor plane are corrected with the help of the microlenses.

In the case of a pin-cushion-shaped distortion, as represented in FIG. 3, the image sensor units and/or the light-sensitive surfaces of the image sensor units can be larger towards the outside and/or have a small filling factor only in the edge region. Whether a pin-cushion- or barrel-shaped distortion of a lens is present, is established by the position of an aperture diaphragm in the total construction of a lens system. The aperture diaphragm should thereby advantageously be disposed such that it is situated between the crucial lens, which can for example be the lens with the greatest refractive power, and/or between the optical main plane and the image sensor in order that a pin-cushion-shaped distortion is produced in order to have a reduced filling factor only in the edge region of the image sensor. The size of the photodiodes within the image sensor units can also be adapted via the array in order to enlarge the filling factor as much as possible. The size of the microlenses can also be correspondingly adapted.

In the case of the image sensor according to the invention and/or in the case of the camera according to the invention, it is important that the light-sensitive surfaces, i.e. the photodiodes, change their spacing relative to each other in order to compensate for a geometric distortion. Whether the photodiodes respectively are thereby situated in the centre or outwith the centre of an image sensor unit, is of equal value during compensation for a geometric distortion. When changing the spacing of the image sensor units relative to each other, the consequently obtained space can be used for increasing the active light-sensitive photodiode surface, which leads to a reduction in the natural vignetting in the edge region.

In FIG. 5, an image sensor 1′ with a distortion correction is illustrated, which image sensor is configured in connection with an imaging lens system 100. The lens system shown here requires no corrections for the geometric distortion since the latter is already integrated completely in the image sensor 1′. The lens 1000 is thereby the lens which has the greatest refractive power within the lens system 100 and hence crucially defines the position of the main plane of the lens system. An aperture diaphragm 101 is fitted in front of the lens system 101 so that a barrel-shaped distortion occurs.

Due to the colour filter grids which are present, colour information can be recorded, by means of a microlens grid also an astigmatism or a field curvature—at least in parts—are already corrected on the image sensor plane. Hence degrees of freedom in the design of the lenses 1000 and 1001 become available, which can be devoted to other aberrations, such as for example the coma or the spherical aberration. The information of the image sensor 1′ is passed on via a data connection 150 to a data processing unit 200 in which a distortion-free lens image can be made available to the observer without great memory or computing time expenditure. Since the image sensor 1′ is coordinated to the lens system 100, the image sensor must be directed in advance corresponding to the main beam path of the lens system. If, for adaptation to the course of the main beam angle, also correspondingly offset filling factor-increasing microlenses (as described for example in FIG. 4), which are also adapted in their shape for optimal focusing, are used in the image sensor, then these can also be adapted to the course of the main beam angle of the lens system which is used. Hence the centring of lens and image sensor is critical since not only the arrangement of the image sensor thereof is influenced with the image circle of the lens to be imaged but also the parameters of the image sensor and/or of the microlenses can have a radial dependency for increasing the filling factor.

A further possibility of configuring the image sensor resides in fitting the image sensor on a curved surface. In this way, a field curvature can be corrected since now all the light-sensitive surfaces have a constant distance from the centre of the lens with the greatest refractive power. Also a constant distance from the centre of a complicated lens system is possible but more complicated in its calculation. The arrangement of the image sensor on a curved surface can however be achieved without difficulty. Likewise, the substrate of the image sensor on which the light-sensitive units are applied can have a corresponding curvature.

In further embodiments, the photodiodes for example can have variable sizes in order to make use in addition of the space obtained by distortion towards the edge. A transverse colour error can be corrected for example on the image sensor side by arrangement of the colour filters, which is adapted correspondingly to the transverse colour filter of the lens system, on the detector pixels or by calculation of the colour pixel signals. The image sensor can be configured also for example to be curved.

The image sensor can for example be an image sensor produced on wafer scale, for example for mobile telephone cameras. In the production of a camera module according to the invention, lens system and image sensor can be designed together. Also for example elliptically chirped microlenses can be applied for focusing in the pixels adapted to the angle of use. For this purpose, for example the radii of curvature of the microlenses can vary in the direction of the two main axes of the ellipses. Also for example a rotation of the elliptical lenses is possible corresponding to the image field coordinate.

Also chirped arrays of refractive microlenses can be used according to an advantageous embodiment. In contrast to standard microlens arrays comprising identical lenses at a constant spacing relative to each other, chirped microlens arrays are constructed from similar but non-identical lenses. The dissociation from the rigid geometry of regular arrays enables optical systems with optimised optical parameters for applications such as e.g. increasing the filling factor in the digital image recording.

Regular microlens arrays (rMLA), as shown in FIG. 6, are used in diverse ways—in sensor technology, for beam formation, for digital photography (increasing filling factor) and in optical telecommunications, to mention only a few. They can be described completely by the number of lenses, the geometry of the constantly repeating unit cell and the spacings relative to the direct neighbours—the pitch. In many cases, the individual cells of the array are used in a different way, which cannot however be taken into account in the design of an rMLA. The geometry of the array found in the optical design represents therefore only a compromise solution.

In contrast to microlens arrays comprising identical lenses with a constant spacing, chirped microlens arrays (cMLA), as are shown for example in FIG. 7, comprise cells which are adapted individually to their task and are defined by means of parametric description. The number of parameters required hereby depends upon the concrete geometry of the lenses. The cell definition can be obtained by analytical functions, numeric optimisation methods or a combination of both. In the case of all chirped arrays, the functions depend upon the position of the respective cell in the array.

A preferred application of chirped microlens arrays is the channel-wise optimisation of the optical function of a repeating arrangement with respect to changing boundary conditions.

CCD- or CMOS image converters are normally planar, the preceding imaging lens system is typically not telecentric, i.e. the main beam angle increases towards the image field edge. An offset dependent upon the angle of incidence between lenses and receptors typically thereby ensures that each pixel can record light with a different (increasing towards the edge) main beam angle of the preceding lens system.

Since the individual lenses must now image from directions which are no longer situated on the optical axis, aberrations of the 3^{rd} order occur, such as astigmatism, field curvature and coma, which impair the imaging quality of the microlenses in the photodiodes and hence reduce the accompanying quantity of light transmitted into the photodiodes (→ reduction in quantum efficiency and/or simply in brightness) (FIG. 8). Advantageously, each microlens transmits a very small opening angle of particularly preferably less than 1° so that an efficient aberration correction is possible by the individual adaptation of the lenses. Advantageously, the photoresist melting (reflow) is suitable for the production of refractive MLA, by means of which lenses with extremely smooth surfaces are produced. After the development of the photoresist irradiated through a mask, the resulting cylinders are hereby melted. As a result of the effect of surface tensions, this leads to the desired lens shape.

The image errors dominant in the lens, astigmatism and field curvature, can be corrected efficiently by the use of anamorphic lenses. Anamorphic lenses, such as for example elliptical lenses which can be produced by reflow, have, in different sectional courses, different surface curvatures and hence focal lengths. By adapting the focal lengths in the tangential and sagittal section, correspondingly modified Gullstrand equations, such as are shown in J. Duparré, F. Wippermann, P. Dannberg, A. Reimann, “Chirped arrays of refractive ellipsoidal microlenses for aberration correction under oblique incidence”, Optics Express, Vol. 13, No. 26, p. 10539-10551, 2005, the focal intercept differences of astigmatism and field curvature can be compensated for individually for each angle and finally a diffraction-limited focus can be achieved for the special field angle of the channel under consideration (FIG. 8).

In contrast to regular microlens arrays (rMLA) which comprise identical lenses in a fixed geometric grid, the individual adaptation of the lenses leads hence to an array arrangement comprising similar but not identical cells. Modified (chirped) cMLA can hence optimise the optical imaging.

The cMLA is defined by analytically derivable equations and designed by adaptation of corresponding parameters. Geometry and position of the elliptical lenses can be described completely with reference to five parameters (centre coordinates in x and y direction, radii of curvature in sagittal and tangential direction, orientation angle), as is shown in FIG. 9. Consequently, five functions which can be derived completely analytically are required for describing the total array. Thus all the lens parameters can be calculated extremely quickly.

The aberration-correcting effect of the anamorphic lenses can be detected in FIG. 10: a spherical lens produces a diffraction-limited spot with vertical incidence. With oblique incidence, the focus in the paraxial image plane will fade greatly as a result of astigmatism and field curvature. In the case of an elliptical lens, with vertical incidence, a widened spot results as a consequence of the different radii of curvature in the tangential and sagittal section. Light which is incident at the design angle, here 32°, again produces a diffraction-limited spot in the paraxial image plane. The cMLA with channel-wise aberration correction enable therewith improvement in the coupling of light through the microlenses into the photodiodes, even with a large main beam angle of the preceding imaging lens system and consequently reduce so-called “shading”.

1. An image sensor having multiple image sensor units in an essentially array-like arrangement, centres of light-sensitive surfaces of the image sensor units being node points at a spacing relative to each other and these, together with horizontal and vertical connection lines, which connect the node points, spanning a two-dimensional network, and the array-like arrangement having a central region and an edge region, the central region and the edge region being connected to each other along at least one connection line, wherein a respective spacing of two adjacent node points of the array-like arrangement is different along the at least one connection line in the central region and in the edge region, and/or the spacing with respect to a second connection line changes from the central region to the edge region so that the network forms a non-equidistant grid.

2. The image sensor according to claim 1, wherein the spacing respectively of two adjacent node points of the array-like arrangement changes constantly along the at least one connection line from the central region to the edge region.

3. The image sensor according to claim 1, wherein the spacing respectively of two adjacent node points of the array-like arrangement changes along the at least one connection line from the central region to the edge region in order to compensate for a geometric distortion.

4. The image sensor according to claim 1, wherein the connection lines of the array-like arrangement form a rectilinear grid.

5. The image sensor according to claim 1 wherein at least one connection line of the array-like arrangement is represented by a parameterised curve.

6. The image sensor according to claim 5, wherein the connection lines of the array-like arrangement form a curvilinear grid.

7. The image sensor according to claim 5, wherein the spacings of adjacent node points of the array-like arrangement change from the central region to the edge region radially symmetrically and/or essentially as a function of the spacing relative to the array central point.

8. The image sensor according to claim 1, wherein the edge region surrounds the central region.

9. The image sensor according to claim 1, wherein the multiple image sensor units are disposed on one substrate.

10. The image sensor according to claim 1, wherein the image sensor units are optoelectronic and/or digital units.

11. The image sensor according to claim 1, wherein, respectively, the light-sensitive surface is disposed in the centre of an image sensor unit.

12. The image sensor according to claim 1, wherein, respectively, the spacing of two adjacent image sensor units is unchanged and, excluding the image sensor units adjacent to the light-sensitive surfaces, the spacing along at least connection line is different.

13. The image sensor according to claim 1, wherein the light-sensitive surface is a photodiode or a detector pixel, a CMOS device, a CCD device, or an organic photodiode.

14. The image sensor according to claim 1, wherein the light-sensitive surface is rectangular or square or hexagonal or round.

15. The image sensor according to claim 1, wherein at least one image sensor unit has a microlens and/or the multiple image sensor units are covered by a microlens grid.

16. The image sensor according to claim 15, wherein the microlens or the microlens grid is configured to increase the filling factor.

17. The image sensor according to claim 15, wherein the microlenses are offset relative to the light-sensitive surfaces for adaptation to a course of a main beam angle of an imaging lens system.

18. The image sensor according claim 15, wherein at least the one microlens is an elliptical microlens with different radii of curvature in two main axes of the elliptical microlens, the microlens being disposed such that a long main axis thereof extends in a direction of a projection of a main beam of an imaging lens system, impinging on the microlens.

19. The image sensor according to claim 18, wherein the at least one elliptical microlens is an elliptical chirped microlens and, for optimal focusing, changes parameters thereof over the array such that it is optimally adapted with respect to the changeable parameters thereof to the conditions which prevail at the respective position thereof.

20. The image sensor according to claim 15, wherein the at least one microlens is adapted in a size thereof variably over the array to the respective spacing of the light-sensitive surfaces in order to increase the filling factor.

21. The image sensor according to claim 1, wherein the light-sensitive surfaces at least of some of the image sensor units have different sizes, preferably the size of the surfaces increasing in the direction from the central region to the edge region.

22. The image sensor unit according to claim 1, wherein at least one image sensor unit has a colour filter for colour image recording, preferably with three basic colours, and/or the multiple image sensor units are covered by a colour filter grid.

23. The image sensor according to claim 22, wherein the colour filters are disposed such that a transverse colour error of the microlenses is corrected and/or the colour filters are disposed deviating from a Bayer pattern and/or from a conventional demosaicing and a known transverse colour error is calculated therefrom by means of an image processing algorithm.

24. The image sensor according to claim 1, wherein the image sensor is configured on a curved surface so that a field curvature is corrected, the image sensor units and/or the light-sensitive surfaces having or being organic photodiodes.

25. A camera system comprising:
an image sensor having multiple image sensor units in an essentially array-like arrangement, centres of light-sensitive surfaces of the image sensor units being node points at a spacing relative to each other and these, together with horizontal and vertical connection lines, which connect the node points, spanning a two-dimensional network, and the array-like arrangement having a central region and an edge region, the central region and the edge region being connected to each other along at least one connection line, where a respective spacing of two adjacent node points of the array-like arrangement is different along the at least one connection line in the central region and in the edge region, and/or the spacing with respect to a second connection line changes from the central region to the edge region so that the network forms a non-equidistant grid; and
an imaging lens system having at least one lens in the image plane of which the image sensor is disposed.

26. The camera system according to claim 25, wherein the spacings respectively of two node points change along at least one connection line of the array-like arrangement of the image sensor units in order to compensate for at least one of: a geometric distortion of the lens system, and a pin-cushion-shaped geometric distortion of the lens system.

27. The camera system according to claim 25, wherein an aperture diaphragm is present: between the image sensor and the imaging lens system, or between the image sensor and a main plane of the lens system.

28. The camera system according to claim 25, wherein the camera system is produced on a wafer.

29. The camera system according to claim 25, disposed in a camera and/or in a portable telecommunications device and/or in a scanner and/or in an image detection device and/or in a monitoring sensor and/or in an earth and/or star sensor and/or in a satellite sensor and/or in a space travel device and/or medical or robotic sensor arrangement.

30. A method for producing an image sensor, the image sensor having multiple image sensor units in an essentially array-like arrangement, centres of light-sensitive surfaces of the image sensor units being node points at a spacing relative to each other and these, together with horizontal and vertical connection lines, which connect the node points, spanning a two-dimensional network, and the array-like arrangement having a central region and an edge region, the central region and the edge region being connected to each other along at least one connection line, where a respective spacing of two adjacent node points of the array-like arrangement is different along the at least one connection line in the central region and in the edge region, and/or the spacing with respect to a second connection line changes from the central region to the edge region so that the network forms a non-equidistant grid, for correcting the distortion of a lens system to be used, the method comprising the following steps:
a) determining the distortion of a planned or already produced imaging lens system;
b) producing an image sensor in which the geometric distortion of the imaging lens system is compensated for at least partially by the arrangement of the light-sensitive surfaces of the image sensor units.

31. The method according to claim 30, wherein, in the design of the imaging lens system, compensation for the geometric distortion is taken into account by the image sensor.

32. The method according to claim 30, wherein the image sensor is connected by an imaging lens system to a functional unit, the lens system having above-average corrections in order to compensate for a chromatic aberration and/or an astigmatism and/or a coma and/or a spherical aberration and/or a field curvature and the geometric distortion being corrected by the image sensor.

33. The method according to claim 30, wherein the method is applied during the production and planning of an imaging lens system and/or an image sensor, said method being used preferably in cameras which are produced on wafer scale.

34. The method according to claim 30, wherein the imaging lens system and the image sensor are designed and/or planned together.
